(19) United States
(12) Patent Application Publication
(10) Pub. No.: US 2006/0072297 A1
(43) Pub. Date: Apr. 6, 2006

(54) Circuit Module Access System and Method

(75) Inventor: Paul Goodwin, Austin, TX (US)

Correspondence Address: J. SCOTT DENKO;ANDREWS & KURTH LLP, 111 CONGRESS AVE.,, SUITE 1700, AUSTIN, 78701, US

(73) Assignee: Staktek Group L.P., Austin, TX (US)

(21) Appl. No.: 10/956,442

(22) Filed: Oct. 1, 2004

(51) Int. Cl. H05K 1/14

(52) U.S. Cl. 361/803

(57) ABSTRACT

Abstract of the Disclosure

One or more connectors are mounted to a module having one or more integrated circuits. In one embodiment, multiple ICs are stacked and interconnected to form a high-density module. The connectors are preferably mounted above the top IC of the module, but may be mounted at other locations. Electrical or fiber-optic cables may be plugged into the connectors. Other devices may be plugged into the connectors. Other embodiments may have one or more connectors mounted to flexible circuitry. Schemes are disclosed to employ various embodiments for test or operational signaling purposes.

### Detailed Description of the Invention

### FIELD:

The present invention relates to interconnects among electronic circuits, and especially to connection topologies for circuit modules.

### BACKGROUND:

A variety of techniques are used to interconnect packaged ICs into high density modules. Some techniques require special packages, while other techniques employ conventional packages. In some techniques, flexible conductors are used to selectively interconnect packaged integrated circuits. Staktek Group, L.P. has developed numerous systems for aggregating packaged ICs in both leaded and CSP (chipscale) packages into space saving topologies.

A CSP package body typically has an array of BGA (ball grid array) contacts along a planar lower side that connect a packaged IC chip to an operating environment. The array of contacts allows a high density of connections between the CSP and an operating environment, such as, for example, a circuit board or stacked high-density circuit module. The density of connections presents, however, difficulties in probing signals at the interior of the array for test purposes. Further, the density of signals in some modern circuits presents a problem for routing input/output and test signals.

Another issue regarding circuit module interconnection is that many typical electronic systems consume too much space in mounting connectors with sockets for electrical signal cables or fiber optic cables. Many times a circuit board will be designed with a footprint for such a connector to be used mainly for test purposes. The use of surface mount connectors, whether for test or operation, may constrain the rest of the system design by using too much valuable board space.

Yet another issue related to connecting with circuit modules arises when ICs are arranged in stacked modules. Many times a signal may be present at a contact within a stack of ICs that may not appear on the input/output contacts of the stack. Such a signal may need to be probed during testing. This is especially true when the stacked module is a “system” module having a significant amount of signaling between ICs in the module. Further, such system modules may require large numbers of input/output signal connections. Often the footprint of a circuit module may not have enough contacts for all desired input/output signal connections.

What is needed, therefore, are methods and structures for stacking circuits in thermally efficient, reliable structures that have adequate input and output connections for testing and operation. What is also needed are methods for interconnecting with integrated circuits to conserve circuit board space.

### SUMMARY:

One or more connectors are mounted to a module having one or more integrated circuits. In one embodiment, multiple ICs are stacked and interconnected to form a high-density module. The connectors are preferably mounted above the top IC of the module, but may be mounted at other locations. Electrical or fiber-optic cables may be plugged into the connectors. Other devices may be plugged into the connectors.

In another embodiment, one or more connectors are mounted to flexible circuitry. The flexible circuitry is wrapped about one or more ICs to make electrical connections from the IC contacts to the connector. Another embodiment connects stacked ICs with flexible circuits wrapped about each stacked IC. The flexible circuits are preferably interconnected with inter-flex contacts. One or more connectors are mounted to one or more of the flex circuits. Module contacts may be used to connect the module to its operating environment.

### BRIEF DESCRIPTION OF THE DRAWINGS:

Fig. 1 depicts a circuit module according to one embodiment of the present invention.

Fig. 2 depicts a top view of the circuit module of Fig. 1.

Fig. 3 depicts an alternative module according to another embodiment of the present invention.

Fig. 4A depicts an exemplar layout of a conductive layer of a flexible circuit according to one embodiment of the present invention.

Fig. 4B depicts an exemplar layout of another conductive layer of a flexible circuit according to one embodiment of the present invention.

Fig. 5 is a cross-sectional view of a portion of flexible circuitry according to a preferred embodiment of the present invention.

Fig. 6 depicts a module 10 according to one alternative embodiment present invention.

Fig. 7 depicts a cross-sectional view of another module according to the present invention.

Fig. 8 depicts a perspective view of another module according to another embodiment of the present invention.

### DETAILED DESCRIPTION OF PREFERRED EMBODIMENTS:

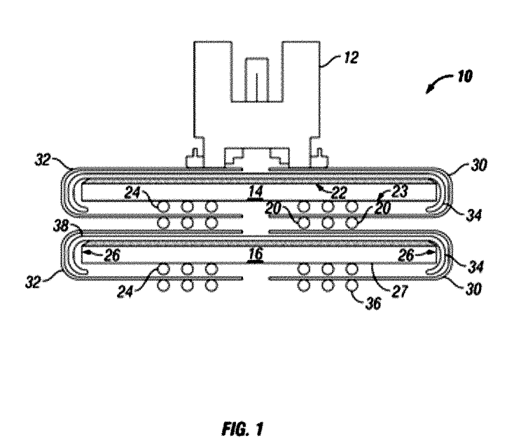

Fig. 1 depicts a circuit module 10 according to one embodiment of the present invention. Connector 12 is mounted to a module 10 having stacked CSPs (Chip-Scale Packaged integrated circuits) 14 and 16. The depicted CSPs 14 and 16 connect to flex circuits 30 and 32 with CSP contacts 24. Inter-flex contacts 20 connect the two depicted sets of flex circuits 30 and 32 to each other. Flex circuits 30 and 32 are wrapped about form standards 34, which are attached to upper major surface 22 of the depicted CSPs 14 and 16. The depicted lower flex circuits 30 and 32 are adapted for connection to an operating environment through module contacts 36.

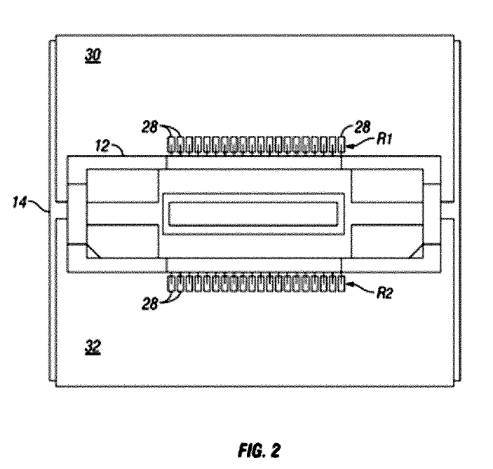

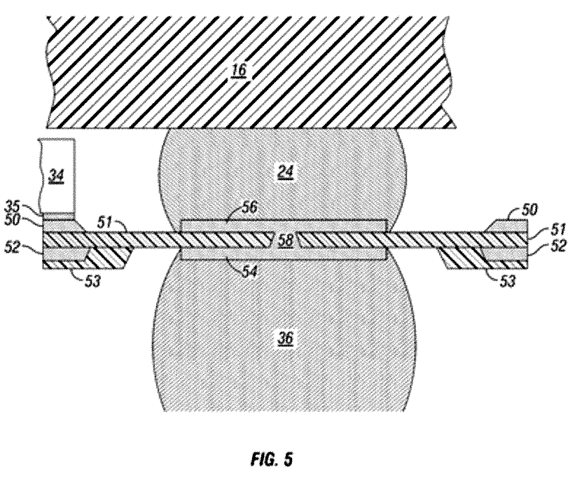

Referring to Figs. 1 and 2, in this embodiment, connector 12 is a MICTOR type connector for attaching a logic analyzer probe. Fig. 2 is a top view of the embodiment depicted in Fig. 1, the view showing connector 12 mounted to mounting pads 28 along the upper sides of flex circuits 30 and 32. Mounting pads 28 are provided in row R1 along the upper side of flex circuit 30 and row R2 along the upper side of flex circuit 32. Rows R1 and R2 together form an array of mounting pads. While in this embodiment, connector 12 mounts to an array on both flex circuits, other embodiments may have a connector mounted only on one flex circuit, or may be provided with different numbers of flex circuits. Other types of connectors may appear on a module 10 in other embodiments. For example, connector 12 may be a socket connector for any type of electrical cable or electrical device. Connector 12 may also be a fiber optic cable connector, for example. Traces on conductive layers (Fig. 5) of flex circuits 30 and 32 connect mounting pads to selected CSP contacts 24 on CSPs 14 and 16. Such connections may be used for temporary measurement and test of signals from within a stack such as the depicted stack of CSPs 14 and 16. Also, such connections may be permanent connections to other circuits that are part of an operating environment for module 10. A combination of traces and inter-flex contacts 20 may also form conductive paths from mounting pads 28 to module contacts 36.

Referring to Fig. 1, in this embodiment, each of the CSPs has an upper surface 22 and a lower surface 23 and opposite lateral edges 25 and 26 and typically include at least one integrated circuit surrounded by a plastic body 27. The body need not be plastic, but a large majority of packages in CSP technologies are plastic. Modules 10 with different sizes of CSPs may be made. The constituent CSPs may be of different types within the same module 10. For example, one of the constituent CSPs may be a typical CSP having lateral edges 25 and 26 that have an appreciable height to present a "side" while other constituent CSPs of the same module 10 may be devised in packages that have lateral edges 25 and 26 that are more in the character of an edge rather than a side having appreciable height. While this embodiment is shown with two CSPs, other embodiments may have one or three or more CSPs. Further, while CSPs are depicted, systems employing leaded packaged ICs may also employ many of the connector configurations disclosed herein.

Flex circuits (“flex”, “flex circuits” or “flexible circuitry”) 30 and 32 are shown wrapped about opposing lateral edges 25 and 26 of CSPs 14 and 16. Some embodiments may employ only one flex circuit, while some may employ multiple flex circuits. An entire flex circuit may be flexible or, as those of skill in the art will recognize, a PCB structure made flexible in certain areas to allow conformability in some areas and rigid in other areas for planarity along contact surfaces may be employed as an alternative flex circuit in the present invention. For example, structures known as rigid-flex may be employed. One embodiment of a such a rigid flex structure places rigid portions in and around areas where CSP contacts 24 are attached to flex circuits 30 and 32, such rigid portions terminating before the depicted bend in each flex circuit 30 and 32. In a preferred embodiment, flex circuits 30 and 32 are multi-layer flexible circuit structures that have at least two conductive layers. Other embodiments may, however, employ flex circuitry having only a single conductive layer.

Preferably, the conductive layers are metal such as alloy 110. The use of plural conductive layers provides advantages such as, for example, the creation of a distributed capacitance across module 10 intended to reduce noise or bounce effects that can, particularly at higher frequencies, degrade signal integrity, as those of skill in the art will recognize. Plural conductive layers may also increase the heat conductivity between different portions of the module 10. Connections between flex circuits are shown as being implemented with inter-flex contacts 20 which are shown as balls but may be low profile contacts constructed with pads and/or rings that are connected with solder paste applications to appropriate connections.

In the depicted embodiment of module 10, form standards 34 are shown disposed adjacent to upper surface 22 of each of the CSPs. Form standard 34 may be fixed to upper surface 22 of the respective CSP with an adhesive 38 which preferably is thermally conductive. Form standard 34 may also, in alternative embodiments, merely lay on upper surface 22 or be separated from upper surface 22 by an air gap or medium such as a thermal slug or non-thermal layer. However, where form standard 34 is a thermally conductive material such as the copper that is employed in a preferred embodiment, layers or gaps interposed between form standard 34 and the respective CSP (other than thermally conductive layers such as adhesive) are not highly preferred.

Form standard 34 is, in a preferred embodiment, devised from copper to create, as shown in the depicted preferred embodiment, a mandrel that mitigates thermal accumulation while providing a standard sized form about which flex circuitry is disposed. Form standard 34 may take other shapes and forms such as for example, an angular "cap" that rests upon the respective CSP body or as another example, it may be folded to increase its cooling surface area while providing an appropriate axial form for the flex that is wrapped about a part of form standard 34. It also need not be thermally enhancing although such attributes are preferable. The form standard 34 allows stacking of CSPs having varying sizes, while articulating a single set of connective structures useable with the varying sizes of CSPs.

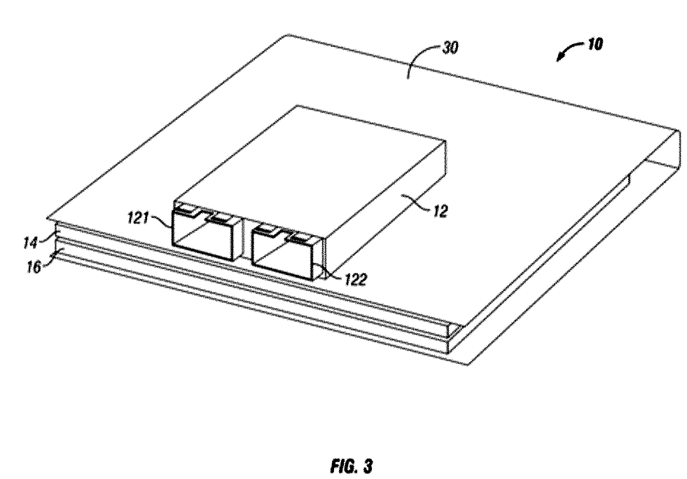

Fig. 3 depicts another embodiment of a module 10. In this embodiment, module 10 has only one flexible circuit 30 connecting CSPs 14 and 16. The depicted CSPs are arranged back-to-back with their upper surfaces 22 oppositely facing. Some embodiments may have thermally conductive adhesive and/or a heat spreader between CSPs 14 and 16. In this embodiment, connector 12 has two connection sockets 121 and 122, which may connect to different cables and/or devices. Connector 12 may include optical-to-electrical and electrical-to-optical conversion circuitry electrically connected to flex 30 for inter-connecting signals between fiber-optic cables and module 10. Other circuitry may be similarly mounted along flex 30. Such circuitry is not shown in this Figure to simplify the depiction.

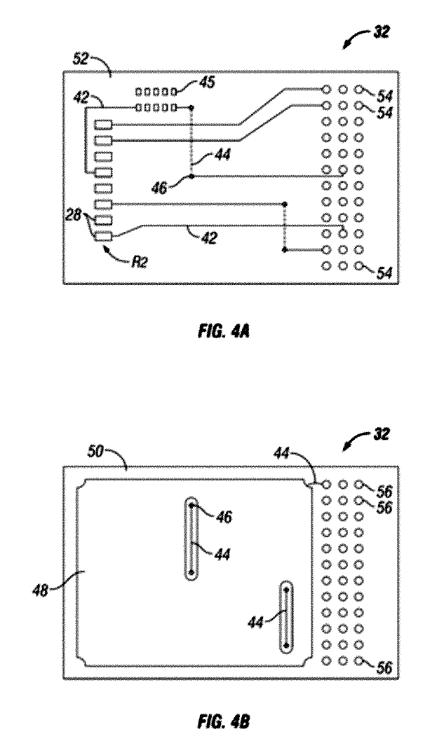

Fig. 4A depicts an exemplar layout of a conductive layer 52 of a flexible circuit 32 according to one embodiment of the present invention. Fig. 4B depicts an exemplar layout of conductive layer 50, which, in this embodiment, is connected to the conductive layer 52 depicted in Fig. 4A. In this embodiment, flexible circuit 32 has a flexible substrate (Fig. 5), with conductive layer 50 on one side of the substrate and conductive layer 52 on the other. Other embodiments may have more flexible substrate layers and more or less conductive layers. The exemplar layouts of conductive layers 50 and 52 depicted in Fig. 4 are both from the same top view. The layers are shown flat, but flex circuit 32 is bent when a module 10 is assembled. After bending, conductive layer 52 is presented at the outside of the bend and conductive layer 50 is presented at the inside.

Referring to Fig. 4A, in this embodiment conductive layer 52 has row R2 of mounting pads 28 for mounting a connector. To simplify the depiction, only a few mounting pads 28 are shown. Other embodiments may have more than row of mounting pads 28 and may present mounting pads for mounting more than one connector. Those of skill will recognize that the one or more rows of mounting pads 28 may be referred to as an “array” or “footprint” for mounting a connector. There may be other footprints expressed by conductive layer 52 for mounting other components. In this embodiment, traces 42 at the level of conductive layer 52 connect mounting pads 28 to footprint 45 and to flex contacts 54. Traces 42 may connect through vias 46 to traces 44 on conductive layer 50. To simplify the depiction, only a few exemplar traces are shown. The depicted exemplar footprint 45 may be used to mount an IC. Other similar footprints may mount other devices such as, for example, discrete components like resistors and capacitors.

Fig. 4A also depicts flex contacts 54. In this embodiment, flex contacts 54 are used to connect to inter-flex contacts such as inter-flex contacts 20 shown in Fig 1. On a flex 32 such as the lower flex 32 depicted in Fig. 1, flex contacts 54 will instead connect to module contacts 36. Flex contacts 54 and 56 further described with reference to Fig. 5.

Fig. 4B depicts an exemplar layout of conductive layer 50. In this embodiment, ground plane 48 covers a large portion of conductive layer 50. Traces 44 connect to vias 46 and flex contacts 56. To simplify the depiction, only a few exemplar traces are shown. Some flex contacts 56 may connect to a corresponding flex contact 54 on conductive layer 52. Other flex contacts 56 may be electrically isolated from the corresponding flex contact 54 on conductive layer 52.

Fig. 5 is a cross-sectional view of a portion of a preferred embodiment depicting a preferred construction for flex circuitry which, in the depicted embodiment is, in particular, flexible circuit 32 which includes two conductive layers 50 and 52 separated by intermediate layer 51. Preferably, the conductive layers are metal such as alloy 110. Intermediate layer 51 is preferably a polyimide substrate, but may be other flexible circuit substrate material.

In the depicted preferred embodiment, flex contact 54 at the level of conductive layer 52 and flex contact 56 at the level of conductive layer 50 provide contact sites to allow connection of module contact 36 and CSP contact 24 through via 58. Other flex contacts 54 may not be so connected by a via 58, but may instead be electrically isolated from their opposing flex contact 56, or may be electrically connected by other structures. While a module contact 36 is shown, the same construction is preferred for an inter-flex contact 20. Further, flex contacts 54 may be presented without a corresponding flex contact 56 in a manner devised to make supplemental inter-flex connections or supplemental module contact connections. Such supplemental connections may be outside in addition to the footprint presented by CSP contact 24 at any level of module 10, and may provide electrical connection between an operating environment and connector 12.

With continuing reference to Fig. 5, optional outer layer 53 is shown over conductive layer 52 and, as those of skill will recognize, other additional layers may be included in flex circuitry employed in the invention, such as a protective inner layer over conductive layer 50, for example. Flexible circuits that employ only a single conductive layer such as, for example, those that employ only a layer such as conductive layer 52 may be readily employed in embodiments of the invention. The use of plural conductive layers provides, however, advantages and the creation of a distributed capacitance across module 10 intended to reduce noise or bounce effects that can, particularly at higher frequencies, degrade signal integrity, as those of skill in the art will recognize. Form standard 34 is seen in the depiction of Fig. 5 attached to conductive layer 50 of flex circuit 30 with metallic bond 35.

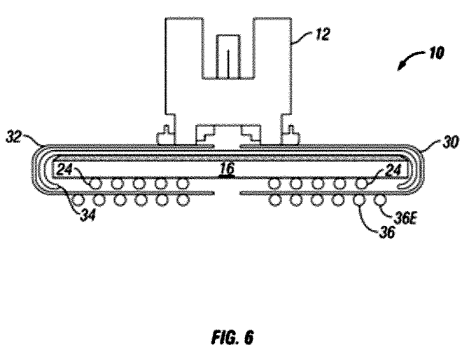

Fig. 6 depicts a module 10 according to one alternative embodiment present invention. In this embodiment, connector 12 is mounted above one CSP 16. Flexible circuits 30 and 32 wrap about curved form standard 34 to connect signals from CSP contacts to connector 12. This embodiment may be employed to advantage to make test connections to hard-to-reach contacts 24. Further, this embodiment may be employed to conserve circuit board space by mounting a connector 12 atop module 10, instead of on a host system circuit board to which module 10 may be mounted. Supplemental module contacts 36E enable module 10 to connect more electrical signals than allowed by the number of contacts in the footprint of CSP contacts 24. While this embodiment has two flexible circuits, 30 and 32, other embodiments may have only one flexible circuit or may have more than two.

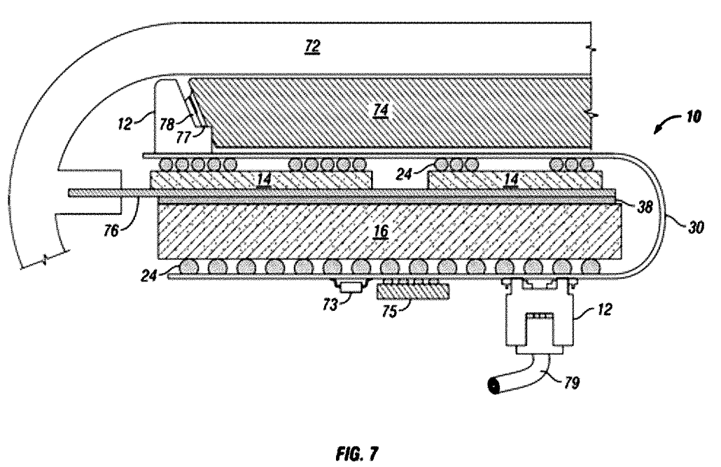

Fig. 7 depicts a cross-sectional view of another module 10 according to the present invention. The depicted circuit module 10 is enclosed in a system casing 72. The shape of casing 72 is merely exemplary and a system casing will vary in size and shape and material for different applications. A module 10 may be employed to advantage in many different systems such as, for example, portable consumer electronics devices and electronic military gear. Typical cases may be made of metal or plastic, for example. In this embodiment, casing 72 holds battery 74, which has contacts 77. The depicted topological arrangement is only exemplary and many other arrangements are possible. Examples of such arrangements include batteries in a separate compartment of housing 72 and batteries connected to connector 12 with wiring. Contacts 78 on the upper depicted connector 12 touch contacts 77 to connect module 10 to battery 74. Another connector 12 is mounted along flex circuit 30. Cable 79 is plugged in to the second connector 12. Cable 79 may carry signals such as user display signals and interface signals, for example, or other types of signals.

The depicted CSPs 16 and 14 are mounted along flexible circuit 30. Discrete component 73 and IC 75 are also mounted along flexible circuit 30. The body of CSP 16 is attached to heat spreader 76 with thermal adhesive 38. Heat spreader 76 is preferably made of metal or other heat conductive material. In this embodiment, heat spreader 76 is mounted to casing 72.

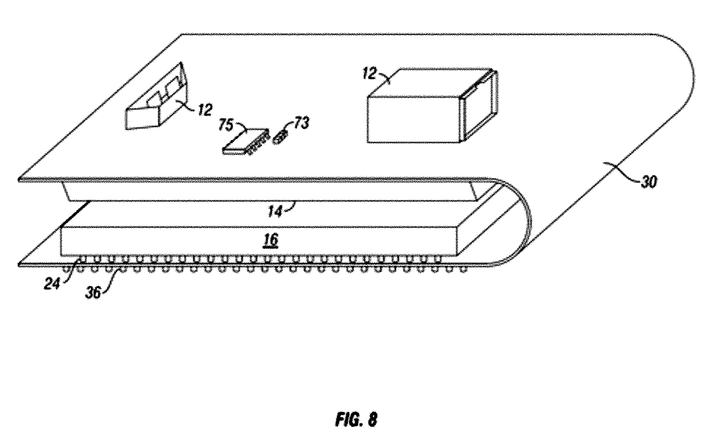

Fig. 8 depicts a perspective view of another alternative embodiment of a module 10 according to the present invention. In this embodiment, two connectors 12 are mounted along the same side of flexible circuit 30. Discrete surface mount component 73 and IC 75 are also mounted along flexible circuit 30. Only one surface mount component 73 and IC 75 are shown, however typical systems will have many more components. Through-hole mount components may also be used. Traces 42 and 44, along with vias 46, (Figs. 4A and 4B) interconnect the various depicted devices. In this embodiment, CSPs 14 and 16 are devices with large numbers of input/output signals conveyed by CSP contacts 24. Examples of such devices are microprocessors, DSPs (digital signal processors), FPGA’s (field-programmable gate arrays) and combinations of such devices along with their support element devices such as, for example, memory devices and D/A and A/D (digital to analog and analog to digital) converters.

Although the present invention has been described in detail, it will be apparent to those skilled in the art that many embodiments taking a variety of specific forms and reflecting changes, substitutions and alterations can be made without departing from the spirit and scope of the invention. The described embodiments illustrate the scope of the claims but do not restrict the scope of the claims.

What is Claimed is:

1. A circuit module including:
first and second CSPs arranged in a vertical stack with the first CSP above the second CSP;
one or more flexible circuits interconnecting the first and second CSPs, the one or more flexible circuits each having a first side and a second side, and one or more conductive layers, the one or more flexible circuits having a selected top flexible circuit, a portion of the selected top flexible circuit being disposed above the first CSP;
a conductive footprint expressed along the first side of the selected top flexible circuit, the conductive footprint for connecting to a surface mount connector.

2. The circuit module of claim 1 in which the surface mount connector is a fiber-optic cable connector.

3. The circuit module of claim 2 further including optical-to-electrical converter circuitry adapted to receive optical signals from a fiber-optic cable in the fiber-optic cable connector.

4. The circuit module of claim 2 further including electrical-to-optical converter circuitry adapted to present optical signals to a fiber-optic cable in the fiber-optic cable connector.

5. The circuit module of claim 1 in which the surface mount connector is an electrical cable connector.

6. The circuit module of claim 1 in which there is a selected bottom one of the one or more flexible circuits, the selected bottom flexible circuit having an array of module contacts for electrically connecting the circuit module to an operating environment.

7. Flexible circuitry including:
one or more conductive layers;
one or more flexible substrates supporting the one or more conductive layers;
an array of surface mount pads expressing a footprint for connection to a connector, the array of surface mount pads being electrically connected to at least one of the one or more conductive layers;
one or more arrays of first flex contacts comprising a plurality of flex contacts for connecting to one or more CSPs each having an upper major surface, the one or more arrays of first flex contacts being electrically connected to at least one of the one or more conductive layers; and
the flexible circuitry devised for wrapping about the one or more CSPs to place the array of surface mount pads above the above upper major surface of at least one of the one or more CSPs and connecting selected ones of the plurality of flex contacts to selected ones of the array of surface mount pads.

8. A high density circuit module including:
flexible circuitry as claimed in claim 7;
one or more first CSPs electrically connected to at least one of the one or more conductive layers of the flexible circuitry;
a connector mounted to the footprint;
one or more inter-stack flexible circuits, each having a flexible substrate supporting one or more conductive layers;
one or more second CSPs electrically connected to at least one of the one or more conductive layers of respective ones of the inter-stack flexible circuits, the one or more second CSPs being in a stacked disposition relative to the one or more first CSPs.

9. The high density module of claim 8 in which there is a selected bottom one of the inter-stack flexible circuits having a plurality of module contacts.

10. The high density module of claim 8 further including a first set of inter-flex contacts and a having selected pair of the inter-stack flexible circuits, the first set of inter-flex contacts being between the selected pair of inter-stack flexible circuits and further including a second set of inter-flex contacts between a selected one of the selected pair of inter-stack flexible circuits and the flex circuitry.

11. A flexible circuit for accessing electrical signals from a ball grid array on a CSP, the flexible circuit including:
a flexible substrate supporting one or more conductive layers;
a set of CSP contacts expressed by at least one of the one or more conductive layers;
a set of module contacts electrically connected to at least one of the one or more conductive layers;
an array of mounting pads arranged as a connector surface mount pad array;
a first set of conductive traces expressed by at least one of the one or more conductive layers, the first set of conductive traces connecting selected ones of the set of CSP contacts to selected ones of the array of mounting pads.

12. The flexible circuit of claim 11 further including a second set of conductive traces expressed by at least one of the one or more conductive layers, the second set of conductive traces connecting selected ones of the module contacts to selected ones of the array of mounting pads.

13. A circuit board assembly including:
a circuit board;
a flexible circuit as claimed in claim 11, the set of module contacts connected to the circuit board;
a CSP mounted to the set of CSP contacts;
a connector mounted to the array of mounting pads.

14. The circuit board assembly of claim 13 in which the flexible circuit has a first side and a second side, the array of mounting pads being presented along a portion of the first side, the set of CSP contacts being presented along a portion of the second side, the flexible circuit being folded about the CSP to present the connector above the CSP.

15. The circuit board assembly of claim 13 in which the flexible circuit has component mounting pads and discrete components mounted to the component mounting pads.

16. 16. The circuit board assembly of claim 13 in which the connector includes one or more sockets for attaching one or more cables.

17. The circuit board assembly of claim 13 in which the flexible circuit further includes optical-to-electrical converter circuitry and electrical-to-optical converter circuitry.

18. A circuit module comprising:
two or more packaged integrated circuits arranged in a stack one above the other, each having a plurality of electrical contacts, the stack having a top one of the two or more packaged integrated circuits;
a connector mounted above the top one of the packaged integrated circuits and electrically connected to at least one of the packaged integrated circuits;
electrical conductors selectively interconnecting the packaged integrated circuits.

19. The circuit module of claim 18 in which the connector is a fiber-optic cable connector.

20. The circuit module of claim 19 further including optical-to-electrical converter circuitry adapted to receive optical signals from a fiber-optic cable in the fiber-optic cable connector.

21. The circuit module of claim 19 further including electrical-to-optical converter circuitry adapted to present optical signals to a fiber-optic cable in the fiber-optic cable connector.

22. The circuit module of claim 18 in which the connector is electrical cable connector.

23. The circuit module of claim 18 in which the connector is a ribbon cable connector.

24. The circuit module of claim 18 further including a flexible circuit electrically connecting the connector to at least one of the two or more packaged integrated circuits.

25. The circuit module of claim 18 further including one or more flexible circuits interconnecting the packaged integrated circuits, the one or more flexible circuits each having one or more conductive layers, selected ones of the one or more conductive layers expressing the electrical conductors.
